(19) United States
(12) Patent Application Publication
(10) Pub. No.: US 2013/0221524 A1
(43) Pub. Date: Aug. 29, 2013

(54) INTEGRATED CIRCUITS WITH IMPROVED INTERCONNECT RELIABILITY USING AN INSULATING MONOLAYER AND METHODS FOR FABRICATING SAME

(71) Applicants: Roderick A. Augur, Hopewell Junction, NY (US); Errol T. Ryan, Clifton Park, NY (US)

(72) Inventors: Roderick A. Augur, Hopewell Junction, NY (US); Errol T. Ryan, Clifton Park, NY (US)

(73) Assignee: GLOBALFOUNDRIES INC., Grand Cayman (KY)

(21) Appl. No.: 13/407,815

(22) Filed: Feb. 29, 2012

(51) Int. Cl. H01L 23/48; H01L 21/56

(52) U.S. Cl. 257/741; 257/734; 438/107; 257/E23.01; 257/E21.502

(57) ABSTRACT

Integrated circuits and methods for fabricating integrated circuits are provided. In an embodiment, an integrated circuit includes an interlayer dielectric material having a top surface and overlying semiconductor devices formed on a semiconductor substrate. The integrated circuit includes a metal interconnect formed in the interlayer dielectric material. The metal interconnect includes an upper surface to which an insulating monolayer is bonded. The integrated circuit further includes a dielectric cap that overlies the top surface of the interlayer dielectric material and encapsulates the insulating monolayer.

### TECHNICAL FIELD

The present disclosure generally relates to integrated circuits and methods for fabricating integrated circuits, and more particularly relates to integrated circuits and methods for fabricating integrated circuits with monolayer insulated metal interconnects.

### BACKGROUND

The fabrication of integrated circuits (ICs) involves the formation of semiconductor devices, such as transistors, resistors and capacitors, on a semiconductor substrate. The semiconductor devices are interconnected to enable the IC to perform the desired functions by forming metal interconnects including contacts, conductive lines, and conductive vias through dielectric material.

As high speed operation and low power consumption has become more critical, copper has become the preferred metal used in metal interconnects. One factor leading to the use of copper in interconnects is its improved resistance to electromigration (EM). Nevertheless, as ICs are miniaturized, current density flowing in copper interconnects is increased and reliability of the copper interconnects against electromigration becomes critical. Electromigration is a phenomenon in which copper atoms diffuse preferentially in the direction of electron flow. EM resistance in the metal interconnect is critical as movement of copper atoms in the interconnect may form voids and electrically open the interconnect. As critical dimensions are reduced, the volume of a void required to cause an open circuit decreases.

Conventional methods of reducing electromigration present other issues. For example, some methods to boost IC performance in EM conditions have resulted in increased line resistance and in increased via resistance. Also, some methods rely on increased line height which results in increased capacitance. Further methods have led to earlier time dependent dielectric breakdown (TDDB). TDDB results in the destruction of the dielectric layer and can cause interconnects to short, rendering the IC defective.

Accordingly, it is desirable to provide integrated circuits and methods for fabricating integrated circuits with reduced electromigration. In addition, it is desirable to provide integrated circuits and methods for fabricating integrated circuits which utilize monolayer insulated interconnects to prevent electromigration. Furthermore, other desirable features and characteristics will become apparent from the subsequent detailed description and the appended claims, taken in conjunction with the accompanying drawings and the foregoing technical field and background.

### BRIEF SUMMARY

Integrated circuits and methods for fabricating integrated circuits are provided. In accordance with one embodiment, an integrated circuit includes an interlayer dielectric material having a top surface and overlying semiconductor devices formed on a semiconductor substrate. The integrated circuit includes a metal interconnect formed in the interlayer dielectric material. The metal interconnect includes an upper surface to which an insulating monolayer is bonded. The integrated circuit further includes a dielectric cap that overlies the top surface of the interlayer dielectric material and encapsulates the insulating monolayer.

In another embodiment, an integrated circuit includes a metal interconnect coupled to underlying semiconductor devices. Further, the integrated circuit includes a dielectric cap selectively bonded to the metal interconnect by molecules. In the embodiment, each molecule has a head group selectively bonded to the metal interconnect and a tail group selectively bonded to the dielectric cap.

In accordance with another embodiment, a method for fabricating an integrated circuit includes depositing an interlayer dielectric material over semiconductor devices. A metal interconnect is formed in the dielectric material. Further, an insulating monolayer is selectively bonded to the metal interconnect. In the method, a dielectric cap is deposited over the insulating monolayer and encapsulates the insulating monolayer.

### BRIEF DESCRIPTION OF THE DRAWINGS

Embodiments of the methods for fabricating integrated circuits will hereinafter be described in conjunction with the following drawing figures, wherein like numerals denote like elements, and wherein:

FIG. 1 illustrates, in cross section, an integrated circuit having a metal interconnect coupled to underlying semiconductor devices formed on a semiconductor substrate in accordance with various embodiments herein.

FIGS. 2-4 illustrate, in cross section, method steps for fabricating the integrated circuit of FIG. 1 in accordance with various embodiments herein; and

FIG. 5 is a schematic illustration of the molecular connection of the insulating monolayer to the metal interconnect and dielectric cap of the integrated circuit in accordance with various embodiments herein.

### DETAILED DESCRIPTION

The following detailed description is merely exemplary in nature and is not intended to limit the integrated circuits or methods for fabricating integrated circuits as claimed herein. Furthermore, there is no intention to be bound by any theory presented in the preceding background or the following detailed description. Also, additional components may be included in the integrated circuits, and additional processes may be included in the fabrication methods but are not described herein for purposes of clarity. For the purposes of explanation, numerous specific details are set forth in order to provide a thorough understanding of exemplary embodiments. It should be apparent, however, that exemplary embodiments may be practiced without these specific details or with an equivalent arrangement.

Integrated circuits and methods for fabricating integrated circuits are contemplated herein. The integrated circuits include insulating monolayers that are formed between metal interconnects and dielectric caps to reduce electromigration of the interconnect metal over the interconnect surface. Further, the insulating monolayers reduce electromigration over the metal interconnect surface without increasing resistance or risk of time dependent dielectric breakdown (TDDB). In fact, use of the insulating monolayers can reduce migration of the interconnect metal ions over the dielectric surface, thus reducing TDDB. The use of the insulating monolayer on the metal interconnect does not change the conductive height, so capacitance is not changed.

Referring to FIG. 1, a method for fabricating an integrated circuit 10 generally includes providing a semiconductor substrate 12 with a surface 14. The semiconductor substrate 12 may be bulk silicon or a silicon on insulator (SOI) wafer. The silicon on insulator (SOI) wafer includes a silicon-containing material layer overlying a silicon oxide layer. In certain embodiments, the semiconductor substrate may be considered to include only the semiconductor layer. While the semiconductor layer is preferably a silicon material, the term “silicon material” is used herein to encompass the relatively pure silicon materials typically used in the semiconductor industry as well as silicon admixed with other elements. Alternatively, the semiconductor layer can be realized as germanium, gallium arsenide, and the like.

As shown, semiconductor devices 16, such as transistors, diodes, resistors, capacitors and the like, are formed on the surface 14 of the semiconductor substrate 12. An interlayer dielectric material 18, such as a low-K dielectric, is deposited over the semiconductor devices 16 and semiconductor substrate 12. Further, a metal interconnect 20 is formed in the interlayer dielectric material 18 and is selectively coupled to the semiconductor devices 16 such as by via 22. As shown, a dielectric cap 24 is deposited over the metal interconnect 20 and interlayer dielectric material 18. Exemplary embodiments herein are provided to reduce electromigration of the interconnect metal along the interface 26 between the metal interconnect 20 and the dielectric cap 24. Further, exemplary embodiments herein also reduce diffusion of the interconnect metal along the interface 28 between the interlayer dielectric material 18 and the dielectric cap 24.

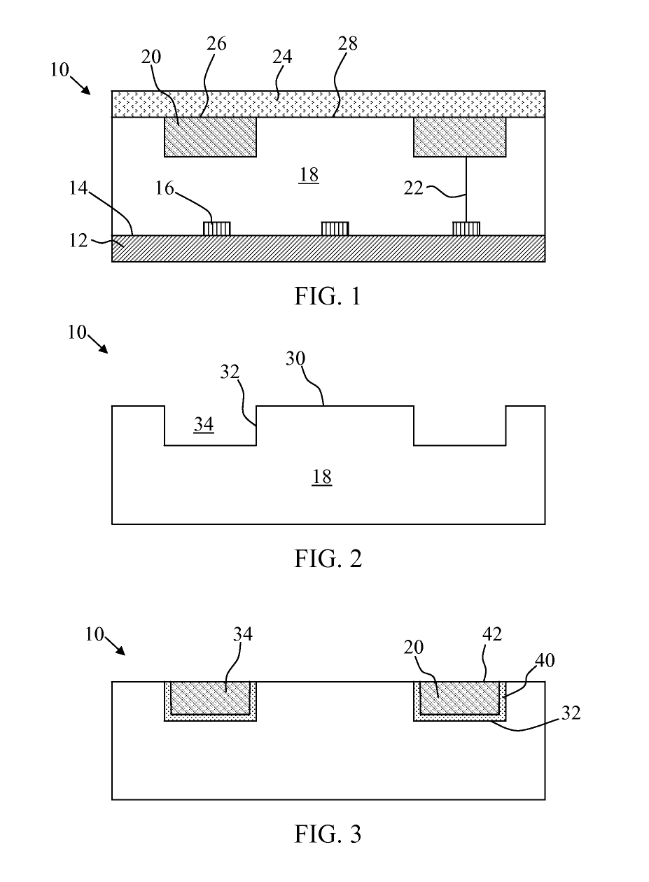

FIG. 2 illustrates the interlayer dielectric material 18 of FIG. 1. In FIG. 2, the top surface 30 of the interlayer dielectric material 18 has been etched to form trench surfaces 32 that define trenches 34. In FIG. 3, a liner 40 is deposited along the trench surfaces 32. The liner 40 is typically formed from a transition metal. A conventional and exemplary liner 40 includes an outer diffusion barrier layer of tantalum nitride formed on the trench surfaces 32, and an inner adhesion layer of tantalum formed on the outer layer. As shown in FIG. 3, the metal interconnect 20, formed by, for example, copper, is deposited in the trenches 34 on the liner 40 and has exposed upper surfaces 42.

In FIG. 4, an insulating monolayer 50 is deposited onto the upper surfaces 42 of the metal interconnect 20. In an exemplary embodiment, the insulating monolayer 50 is deposited by condensing monolayer molecules from the vapor phase to liquid on the upper surfaces 42 of the metal interconnect 20. After the monolayer 50 is deposited, the dielectric cap 24 is deposited over the monolayer 50 and interlayer dielectric material 18, encapsulating the monolayer 50. In an exemplary embodiment, the dielectric cap has a thickness of about 15 nm to about 100 nm. An exemplary dielectric cap 24 is a nitrogen-doped silicon carbide layer. A typical deposition process for such material is low pressure chemical vapor deposition (LPCVD). In certain embodiments, the cap 24 is deposited by plasma-enhanced chemical vapor deposition (PECVD). More specifically, the cap 24 may include a first layer dielectric 44 deposited by atomic layer deposition (ALD) or plasma enhanced atomic layer deposition (PEALD) over the monolayer 50 and the interlayer dielectric material 18, and a second layer dielectric 46 deposited by PECVD over the first layer 44. After formation of the dielectric cap 24, conventional processing is performed to complete the integrated circuit 10.

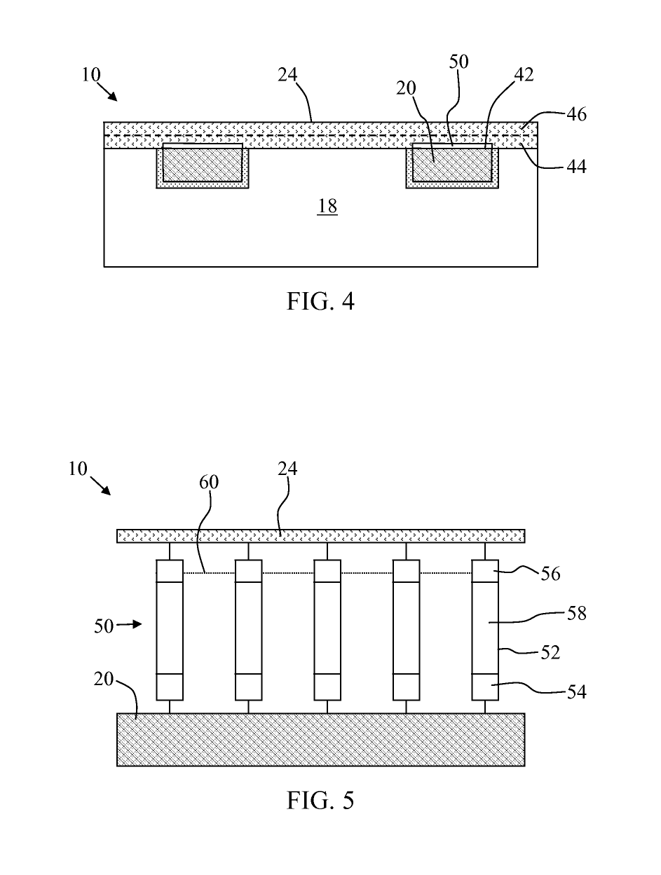

Referring to FIG. 5, the structure of the monolayer 50 is illustrated. As shown, the exemplary monolayer 50 is includes a single layer of molecules 52 which form a self-assembled monolayer (SAM). Each molecule 52 includes a head group 54 that selectively bonds to the metal interconnect 20. Further, each molecule 52 includes a tail group 56 that selectively bonds to the dielectric cap 24. Also, each molecule 52 includes a backbone structure 58 that interconnects the head group 54 and the tail group 56.

In an exemplary embodiment, the head group 54 is a —SHx group. Upon deposition of the monolayer 50, a bond is selectively formed between the S and a copper molecule in the metal interconnect 20 while the tail group 56 will not bond to the copper. The exemplary tail group 56 is a —Si(OR)x group. When the dielectric cap 24 is deposited, a bond is selectively formed between an oxygen atom in the tail group 56 and the dielectric cap material 24. Adjacent molecules 52 may be bonded together via Si—O—Si bonds 60, with each molecule 52 sharing the intermediate oxygen atom. The backbone 58 interconnecting the head group 54 and the tail group 56 must have sufficient thermal stability to withstand the dielectric cap deposition conditions, which typically include temperatures of at least about 150° C. For example, an exemplary backbone 58 has sufficient thermal stability to withstand the dielectric cap deposition conditions at about 380° C. An exemplary backbone 58 is silicon-based, such as a siloxane chain (R₂SiO)ₓ, wherein R is a hydrogen or hydrocarbon chain.

During formation of the monolayer 50 and dielectric cap 24, oxidation is an issue. Specifically, the monolayer 50 may not prevent oxidation of the metal interconnect 20 in an oxygen environment. Therefore an oxygen-free chamber or connected chambers may be utilized to prevent exposure of the integrated circuit 10 to oxygen. During formation of the monolayer, the integrated circuit 10 is positioned in a low pressure chamber. Monolayer molecules in vapor form are introduced in the chamber so that the monolayer molecules 52 condense onto the metal interconnect 20. Additionally, the monolayer molecules 52 may condense onto the exposed portion of the liner 40. After deposition of the monolayer 50, the dielectric cap 24 is formed, such as through the two-layer process described above. Further, a copper oxide reduction step may be performed before forming the monolayer 50. Specifically, a thermal or plasma pre-clean process may be used to eliminate copper oxide from the metal interconnect 20.

Integrated circuits formed in accordance with the methods herein exhibit improved resistance to electromigration and TDDB. Specifically, the integrated circuits 10 are formed with a metal interconnect 20 insulated with a monolayer 50 that is encapsulated by a dielectric cap 24. The monolayer 50 effectively insulates the metal interconnect 20 and prevents electromigration of the interconnect metal, for example, copper, along the upper surface 42 of the metal interconnect. Further, the monolayer 50 prevents leakage and migration of the interconnect metal along the interface 28 between the dielectric cap 24 and the interlayer dielectric material 18, thereby reduce TDDB.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. An integrated circuit comprising:
an interlayer dielectric material having a top surface and overlying semiconductor devices formed on a semiconductor substrate;
a metal interconnect formed in the interlayer dielectric material and having an upper surface;
an insulating monolayer bonded to the upper surface of the metal interconnect; and
a dielectric cap overlying the top surface of the interlayer dielectric material, and encapsulating the insulating monolayer.

2. The integrated circuit of claim 1 wherein the metal interconnect is copper.

3. The integrated circuit of claim 1 wherein the interlayer dielectric material is a low-K dielectric.

4. The integrated circuit of claim 1 wherein the interlayer dielectric material includes trench surfaces defining a trench, wherein the integrated circuit further comprises a liner formed on the trench surfaces, and wherein the metal interconnect in formed on the liner in the trench.

5. The integrated circuit of claim 1 wherein the insulating monolayer is a self-assembled monolayer (SAM) formed from molecules, and wherein each molecule has a head group configured to selectively bond to the metal interconnect.

6. The integrated circuit of claim 5 wherein each head group is a —SHx group.

7. The integrated circuit of claim 5 wherein each molecule has a tail group that selectively bonds to the dielectric cap.

8. The integrated circuit of claim 7 wherein each tail group is a —Si(OR)x group.

9. The integrated circuit of claim 5 wherein each molecule has a backbone interconnecting the head group and the tail group.

10. The integrated circuit of claim 9 wherein each molecule has a backbone with thermal stability sufficient to withstand thermal exposure to at least 150° C.

11. The integrated circuit of claim 10 wherein the backbone is a siloxane backbone.

12. The integrated circuit of claim 5 wherein the SAM is a vapor-condensed SAM.

13. The integrated circuit of claim 1 wherein the dielectric cap is a PECVD-deposited dielectric cap.

14. The integrated circuit of claim 1 wherein the cap comprises a first layer ALD- or PEALD-deposited dielectric positioned over the SAM and the interlayer dielectric material, and a second layer PECVD-deposited dielectric positioned over the first layer.

15. An integrated circuit comprising:
a metal interconnect coupled to underlying semiconductor devices; and
a dielectric cap selectively bonded to the metal interconnect by molecules, wherein each molecule has a head group selectively bonded to the metal interconnect and a tail group selectively bonded to the dielectric cap.

16. The integrated circuit of claim 15 wherein the molecules form a self-assembled monolayer.

17. The integrated circuit of claim 16 wherein the head group is a —SHx group, and the tail group is a —Si(OR)x group.

18. The integrated circuit of claim 16 wherein each molecule includes a backbone interconnecting the head group and the tail group, and wherein the backbone has thermal stability sufficient to withstand thermal exposure to at least 150° C.

19. The integrated circuit of claim 18 wherein the backbone is a siloxane backbone.

20. A method of fabricating an integrated circuit comprising:
depositing an interlayer dielectric material over semiconductor devices;
forming a metal interconnect in the dielectric material;
selectively bonding an insulating monolayer to the metal interconnect; and
depositing a dielectric cap over the insulating monolayer and encapsulating the insulating monolayer.
